(19) United States
(12) Patent Application Publication
(10) Pub. No.: US 2019/0023529 A1
(43) Pub. Date: Jan. 24, 2019

(54) SYSTEM AND METHOD FOR MANAGING AND MONITORING LIFTING SYSTEMS AND BUILDING FACILITIES

(71) Applicant: Chun Ming LAU, Hong Kong (HK)

(72) Inventor: Chun Ming LAU, Hong Kong (HK)

(21) Appl. No.: 16/038,205

(22) Filed: Jul. 18, 2018

(30) Foreign Application Priority Data
Jul. 18, 2017 (HK) 17107223.5
Jul. 18, 2017 (HK) 17110067.8
Oct. 16, 2017 (EP) 17196719.3

(51) Int. Cl. B66B 5/00; B66B 5/14; B66B 5/04; G01N 25/18; G01R 11/00

(52) U.S. Cl. CPC B66B 5/0025; B66B 5/14; G01R 11/00; B66B 5/04; G01N 25/18; B66B 5/0012

(57) ABSTRACT

It is provided interactive system and method for monitoring and reporting building facilities' life cycle, maintenance, and metrics audit, comprising: sensing modules for collecting operation data of the building facilities; processors configured to: receive and store the collected operation data; simulate a building information model (BIM) of the building using the collected operation data; construct a three-dimensional model of the building using the collected operation data; generate the building facilities' life cycle, maintenance, and metrics audit reports using the collected operation data; compute a present carbon dioxide emission of the building; and predict a future carbon dioxide emission of the building; communication modules, each electrically connected to one of the processors, for communicating with a control center; wherein the control center comprising networked user interfaces, for accessing and retrieving data from the processors and data tracking systems for automatic, intelligent, remote report re-test and retro-commissioning (RCx).

### CROSS-REFERENCE TO RELATED APPLICATIONS

The present application claims priority to the Hong Kong Short-term Patent Application No. 17107223.5 filed Jul. 18, 2017; Hong Kong Short-term Patent Application No. 17110067.8 filed Jul. 18, 2017 and the European Patent Application No. 17196719.3 filed Oct. 16, 2017; the disclosures of which are incorporated herein by reference in their entirety.

### TECHNICAL FIELD

The present invention relates to a management, monitoring, and reporting system for monitoring the conditions of building facilities such as lifting systems. Further, the present invention related to estimating life cycles of the lifting system for Lift Maintenance and Measure Audit report (LMAR).

### BACKGROUND

Nowadays, improving energy efficiency of buildings has become a “major task”. Architects, engineers, planners, developers and builders are proposing more and more “passive” and low energy buildings with a much lower energy consumption for facilities of various functions such as heating, air-conditioning, lighting. It may go further to propose “energy-positive” buildings which produce more energy than they consume. The trend is clear in all types of constructions, from individual houses to residential complexes, from industrial halls to administrative buildings. The soaring cost of energy is the prime reason for this rapid evolution. Moreover, the increased consciousness brought by the debate on climate change and the perception that fossil fuels are limited in time has made it become a main priority for the construction sector. The concentration of carbon dioxide CO₂, the culprit of global warming, has increased by over 40 percent since pre-industrial times. Such increase is primarily due to burning of fossil fuels and secondarily due to deforestation. Its present-day concentration is the highest over the last 800,000 years. One of the toughest challenges we have for a sustainable future is to reduce consumption of raw material.

Since the time when people have more than one floors in a building, they have to give consideration to some forms of vertical movement. The daily fights to overcome gravity has led people to explore and develop various technologies. In a building, the basic elements needed to make a rope system for a lifting system are the load support, a suspension means (such as ropes) and a lifting machine located at a high position. There are various layouts for rope system, such as overhead, bottom drive, single wrap, double wrap, with or without compensation ropes etc.

In the lifting system, lifts are usually attached to a number of ropes and/or cables that are roved over a sheave and attached at the other end to a counterweight. Rope and/or cable tension uneveness when roving over a sheave may cause several cost and safety problems. In fact, it is hardly possible to have a wear-minimizing setting of rope tension by conventional means. Regarding methods for tensioning, even if the workers are able to measure the tension of each rope, the setting would be performed by trial and error. The workers would sense and approach the optimal rope adjustment in a way that the tension of each rope is set by tightening or relaxing each rope several times in small increments. This procedure of rope setting costs a lot of time. During lift installation, various load distributions in the rope set during the ride can be considered to feature ideal rope tensions. The loading on the rope can be measured on the drive and then displayed and evaluated in the sensor suite. As a result, the user may receive and execute the optimal rope tension values to get the smallest possible wear of the ropes caused by individual rope tensions. The rope setting should be checked periodically, since the load distribution in the rope set may change over time. One of the problems the designer of a traction lift should carefully evaluate is the uncontrolled movement of a lift car due to the loss or excess of traction of the ropes in the pulley grooves of the traction sheave, which is regulated under the clause 1.4.4 of the Lifts Directive 95/16/EC.

### SUMMARY OF THE INVENTION

It is one of objectives of the invention to provide an intelligent automatic remote system for the maintenance and auditing of lifting systems. The intelligent automatic remote system can be used for maintaining acceptable environmental conditions in lifting systems by carrying out one or more control processes. Since lifting systems are hardware-intensive, their initial installation and maintenance costs can be substantial. There are also problems of performance inaccuracy, mechanical wear, and inflexibility in the ongoing operation of the lifting systems. The deployment of the intelligent automatic remote system can minimize the number of hours the elevator is out of order. It can also minimize the maintenance time and repair time.

In accordance to one aspect of the present invention, provided is a system for monitoring operations of a lifting system comprising one or more lifts and one or more counterweights, comprising: one or more load sensors, each installed on a suspension means or lift equipment, for collecting lift operation data comprising tension profile, power consumption, and loading of the lift, wherein the suspension means comprises one or more ropes, cables and one or more tracking pulleys; a load control unit for controlling the movement of the lifts; a processor, electrically connected to the load control unit, configured to execute an optimization process to optimize load distribution in the suspension means and the power consumption of the lift; one or more remote processors configured to receive and store the lift operation data; a communication module, electrically connected to the processor, for communicating with the remote processors and a control center; and the control center comprising one or more networked user interfaces, for accessing and retrieving data from the remote processors. The operation data generated by the load sensors are sent to and collected by the remote processors; wherein the remote processors are further configured to analyze the collected operation data for detection of abnormal operation, including excessive wear in the suspension means or lift equipment and fatigue in the ropes and cables, of the lifting system; and wherein the remote processors are further configured to generate a Lift Maintenance and Measure Audit Report (LMAR) from the collected operation data.

In accordance to one embodiment, the aforesaid system further comprises a plurality of noise sensors for collecting noise data for determination of the load distribution evenness of the cables in the suspension means; wherein at least one of the load sensors is integrated with a wired or wireless transmitter for transmitting the lift operation data to the load control unit; wherein at least one of the noise sensors is integrated with a wired or wireless transmitter for transmitting the noise data to the load control unit; and wherein the load control unit is integrated with a wired or wireless transceivers for receiving lift operation data from the load sensors and transmitting data signals to the remote processors for audit control.

In accordance to another embodiment, the aforesaid system further comprises: one or more electric drives for actuating movements of the lift; one or more isolating switches, each installed between a motor control panel and an electrical power supply, for allocating currents to the electric drives according to the power consumption of the lifting system measured by the load sensors; and one or more regenerative energy storage assemblies, each respectively connected to one of the isolating switches, for storing electrical energy regenerated during movements of the lift cars and/or counterweights, and feeding the stored electrical energy into the lifting system or an electricity distribution network.

In accordance to another embodiment, the aforesaid system further comprises: one or more cameras, for capturing the lift movements and passenger flow for simulating the lift cars' flights; one or more door sensors, each installed in one of the lift, for detecting whether the lift car's doors are opened or closed; and one or more hoist brakes and braking means, wherein each of the hoist brake or braking means is urged to hold the lift car when the door sensor in the lift detects that the doors of the lift are opened. The simulation of the lift cars' flights for arranging lift zoning in which the building floors are divided into a plurality of clusters of stops each to be served by one or more of the lift cars.

In accordance to another embodiment, the aforesaid system further comprises one or more fire or smoke detectors, each installed in one of the one or more lift shafts and building facilities for detecting presence of fire and transmitting a fire detection signal to the load control unit when the presence of fire is detected; a fire alarm system; wherein the load control unit automatically initiates the fire alarm operation; and wherein the fire alarm system operation comprises moving the lift cars to a safety floor when the fire detection signal is received.

In accordance to another embodiment, the aforesaid fire alarm system comprises one or more ventilation ports located above at least one of the lift shafts; wherein at least one of the ventilation ports is installed with a solar thermal-energy exchange window; wherein the solar thermal-energy exchange window is closed for energy generation under normal condition and caused to open for ventilation when the presence of fire is detected.

In accordance to another aspect of the present invention, provided is a system for monitoring and reporting one or more building facilities' life cycle, maintenance, and metrics audit, comprising: one or more sensing modules for collecting operation data of the one or more building facilities; one or more processors configured to: receive and store the collected operation data; simulating a building information model (BIM) of the building using the collected operation data; generate the one or more building facilities' life cycle, maintenance, and metrics audit reports using the collected operation data; compute a present carbon dioxide emission of the building; and predict a future carbon dioxide emission of the building; and wherein the BIM provides a representation of physical and functional characteristics of the building to facilitate decision making on performance and operational improvements.

In accordance to one embodiment, the aforesaid sensing modules comprise one or more load sensors, each installed on a suspension means in at least one of the buildings' lifts for collecting lift operation data comprising cable tension profile and loading of the lift; one or more electrical transformers, each installed in an electrical power circuit of one of the building facilities for measuring electrical and/or voltage of the building facility's electricity consumption; one or more fire or smoke detectors, each installed in one of the one or more building lift shafts, for detecting presence of fire and transmitting a fire detection signal to the load control unit when the presence of fire is detected.

In accordance to another embodiment, the aforesaid system further comprises a fire alarm system comprising one or more ventilation ports located above the lift shafts, wherein the ventilation ports are caused to be opened when there is the presence of fire is detected; wherein the fire alarm system operation comprises moving the lifts to a safety floor when the fire detection signal is received and operating one or more of water pumps, drainage pumps and sewage pumps, fire pumps under the lift shafts.

In accordance to another embodiment, the aforesaid system further comprises one or more photovoltaic solar electricity generation units; wherein the photovoltaic solar electricity generation units comprise one or more building windows and building glass wall coated with transparent photovoltaic material and electrically connected to an electricity storage station; wherein aforesaid system further comprises a ventilation system comprising one or more ventilation ports located above at least one of the building lift shafts; wherein at least one of the ventilation ports is installed with one or more of the coated building windows; and wherein the coated building windows installed at the ventilation ports are caused to open for heat dissipation; and wherein excess electricity generated by the one or more photovoltaic solar electricity generation units is redistributed into an electricity distribution network; and wherein the excess electricity and the present carbon dioxide emission are used in carbon trading computation.

In accordance to another embodiment, the aforesaid system further comprises one or more solar thermal-energy exchange units comprising one or more building windows coated with transparent thermal absorbing material and connected to a thermal-electricity conversion layer; wherein the thermal-electricity conversion layer is a piezoelectric coating on the coated building window electrically connected to an electricity storage station; wherein the aforesaid system further comprises a ventilation system comprising one or more ventilation ports located above at least one of the building lift shafts; wherein at least one of the ventilation ports is installed with one or more of the coated building windows; wherein the coated building windows installed at the ventilation ports are closed for energy generation from the lift shafts heat under normal condition and are caused to open for heat dissipation; and wherein excess electricity generated by the one or more photovoltaic solar electricity generation units is redistributed into an electricity distribution network; and wherein the excess electricity and the present carbon dioxide emission are used in carbon trading computation.

### BRIEF DESCRIPTION OF THE DRAWINGS

The problem to be solved of the invention will be apparent upon consideration of the following description given herein below and the accompanying drawings which are given by way of illustration only, and thus are not limitative of the present invention. In the drawings, wherein like reference delineate similar elements throughout the several views:

FIG. 1 is a block diagram in accordance with the data operation and configuration of one embodiment of the intelligent automatic remote system;

FIG. 2 is an illustrative block diagram of one embodiment of the intelligent automatic remote system;

FIG. 3 is an illustrative diagram showing different running modes of a lifting system in one embodiment of the intelligent automatic remote system;

FIG. 4 is an illustrative diagram showing the connection of isolating switches in one embodiment of the intelligent automatic remote system; and

FIG. 5 is an illustrative diagram showing power regeneration and data integration in one embodiment of the intelligent automatic remote system at different running modes of the lifting system.

### DETAILED DESCRIPTION OF EMBODIMENTS

In some embodiments of the present invention, a system is provided for monitoring and reporting one or more building facilities' life cycle, maintenance, and metrics audit, comprising: one or more sensing modules for collecting operation data of the one or more building facilities; one or more processors configured to: receive and store the collected operation data; simulating a building information model (BIM) of the building using the collected operation data; constructing a three-dimensional model of the building; generate the one or more building facilities' life cycle, maintenance, and metrics audit reports using the collected operation data; compute a present carbon dioxide emission of the building; and predict a future carbon dioxide emission of the building; one or more communication modules, each electrically connected to one of the processors, for communicating with a control center; wherein the control center comprising one or more networked user interfaces, for accessing and retrieving data from the processors; and wherein the BIM provides a representation of physical and functional characteristics of the building to facilitate decision making on performance and operational improvements.

In some other embodiments of the present invention, the aforesaid sensing modules comprise one or more load sensors, each installed on a suspension means in at least one of the buildings' lifts for collecting lift operation data comprising cable tension profile and loading of the lift; one or more electrical transformers, each installed in an electrical power circuit of one of the building facilities for measuring electrical and/or voltage of the building facility's electricity consumption; one or more fire or smoke detectors, each installed in one of the one or more building lift shafts, for detecting presence of fire and transmitting a fire detection signal to the load control unit when the presence of fire is detected.

In some other embodiments of the present invention, the system for monitoring and reporting one or more building facilities' life cycle, maintenance, and metrics audit may further comprise a fire alarm system comprising one or more ventilation ports located above the lift shafts, wherein the ventilation ports are caused to be opened when there is the presence of fire is detected; wherein the fire alarm system operation comprises moving the lifts to a safety floor, which would be the first floor where the main entrance is located, when the fire detection signal is received and operating one or more of water pumps, drainage pumps and sewage pumps, fire pumps under the lift shafts.

In some embodiments of the present invention, the system for monitoring and reporting one or more building facilities' life cycle, maintenance, and metrics audit may further comprise: one or more electrical transformers, each installed in an electrical power circuit of one of the building facilities for measuring electrical and/or voltage of the building facility's electricity consumption; one or more electricity storage stations for storing electrical energy regenerated in one of the building facilities; one or more photovoltaic and heat-exchange generation units to generate and store electrical energy for further reducing energy consumption and effectively enhancing energy gain. In some existing buildings, large amount of energy is consumed. Under the chimney effect, the air inside the well channel raise after being heated up, diffused out of the building through the openings at the top of lift shafts. The system may further comprise openings at the top of lift shafts configured with windows (or blinds) and photovoltaic/heat-exchange generation units to facilitate exhausting of heat energy, ventilation and energy collection. For example, the photovoltaic generator may comprise a transparent energy conversion coatings on the surface of building window glass above lift shafts such that solar energy can be used for electricity generation in lift shafts. With solar-energy conversion coating, the lift shafts can become a storage station of electrical energy.

The above-said transparent energy conversion coatings may be applied on glass or plastic surface such that the originally heat absorptive window glasses or similar materials can be converted to electrical generator devices to generate electricity via solar energy and heat.

Through high pressure and high temperature processing, the transparent energy conversion coatings can be used as a heat absorbing layer in glass lift shafts. Applicable solar-energy heat absorbing coatings may be deposited by means of electrical plating, anodized plating or vacuum deposition technics. Such technologies have been widely adopted in energy storage and recycling, in the applications such as Drones, unmanned flying vehicles or remote database service etc.

In some other embodiments of the present invention, the system for monitoring and reporting one or more building facilities' life cycle, maintenance, and metrics audit may further comprise one or more photovoltaic solar electricity generation units; wherein the photovoltaic solar electricity generation units comprise one or more building windows and building glass wall coated with transparent photovoltaic material and electrically connected to an electricity storage station; wherein aforesaid system further comprises a ventilation system comprising one or more ventilation ports located above at least one of the building lift shafts; wherein at least one of the ventilation ports is installed with one or more of the coated building windows; and wherein the coated building windows installed at the ventilation ports are caused to open for heat dissipation; and wherein excess electricity generated by the one or more photovoltaic solar electricity generation units is redistributed into an electricity distribution network; and wherein the excess electricity and the present carbon dioxide emission are used in carbon trading computation.

In some other embodiments of the present invention, the system for monitoring and reporting one or more building facilities' life cycle, maintenance, and metrics audit may further comprise one or more solar thermal-energy exchange units comprising one or more building windows coated with transparent thermal absorbing material and connected to a thermal-electricity conversion layer; wherein the thermal-electricity conversion layer is a piezoelectric coating on the coated building window electrically connected to an electricity storage station; wherein the aforesaid system further comprises a ventilation system comprising one or more ventilation ports located above at least one of the building lift shafts; wherein at least one of the ventilation ports is installed with one or more of the coated building windows; wherein the coated building windows installed at the ventilation ports are closed for energy generation from the lift shafts heat under normal condition and are caused to open for heat dissipation; and wherein excess electricity generated by the one or more photovoltaic solar electricity generation units is redistributed into an electricity distribution network; and wherein the excess electricity and the present carbon dioxide emission are used in carbon trading computation.

The major materials for making solar-powered unmanned flying vehicles, such as soft magnetic material (e.g. Gd) or polyvinylidene difluoride (PVDF) piezoelectric coating, may be used in aforesaid solar thermal-energy exchange units to collect and store wasted heat energy. At smaller heat gradient, after acquiring mechanical vibration, such wasted heat energy may be converted to usable electrical energy. Also, the heat transfer efficiency would be higher because of the smaller heat gradient.

In some embodiments of the present invention, afore-said solar thermal-energy exchange units may be made of soft magnetic material such as Gadolinium (Gd) and hard magnetic material such as Neodymium (Nd). During operation, excess heat enters a heat diffuser, the damping-connected soft magnetic material is in contact with a heat storage device, and the solar-energy integration module absorbs heat energy generated by the heat source and converted the same to usable electrical energy. Said heat storage device is located close to the top of lift shaft and heat source, that is in connection with the ventilation ports. Being driven by the high and low electric potentials, magnetic oscillation occurs and cause phase change in the soft magnet from ferromagnetic state to paramagnetic state, and then from paramagnetic state to ferromagnetic state. Mechanical energy due to such piezoelectric effect is then converted to electrical energy. On the other hand, heat energy generated in the heat source is dissipated through the soft magnetic material after diffusing into the heat diffuser. Then, the soft magnet returns to the ferromagnetic state, the magnetic force is enhanced, under the action of hard magnet, the suspension arm is continuously mechanically deformed, the mechanical energy generated is then converted into electrical energy via piezoelectric effect.

In some embodiments of the present invention, each components of the system for monitoring and reporting one or more building facilities' life cycle, maintenance, and metrics audit are assigned with IP address for internet access, so as to realize comprehensive building monitoring, control system and facilitate operation of the fire alarm system through communication with water pumps, drainage pumps and sewage pumps, fire pumps under the lift shafts.

In some embodiments of the invention, the system for monitoring and reporting one or more building facilities' life cycle, maintenance, and metrics audit may be established with a Intelligence Remote Storage and a Smart Network System via wired/wireless data transmission with various wiring connected with power supply and/or power line carrier. The Smart Network System realizes the transmission of information such as rope tensioning equalization, load weighting, irregularities in starting, stopping, etc., between the rope with related equipments and the Intelligence Remote Storage; and records the ratios between balanced load, overload, no-load, full-load, peak time, and similar data by interfacing with CCTV system, the lift power metering under loading and unloading conditions, riding quality by interfacing with power metering, monitors the storage of regenerative power used by different running mode of lifts interfacing with power supply and metering; protects the passenger and lift equipment from overload and over-traction by interfacing with power supply and metering; pre-checks the power to insure health operation when leaving each floor or landing by interfacing with power metering, audits equipment safety compliance; inspects critical parts by remote examination and measurement, maintenance and adjustment quality, visual inspection by interfacing with remote monitoring system; maximizes elevator operation by ignoring hall calls with a full cab or ignoring car calls with an empty car, scanning, analyzer and logger system by interfacing with Building Model System (BMS). LMAR may be operated in a private network that only permits particular users, that is associated with the change link to the TMMS together with the Power, Energy and Maintenance Cost Control (PEMCC). Further, the system can help to audit periodic maintenance plans, risk based model include age and time of last inspection; compare the lift operation audit report with the records of building management. One can audit the lift operation in real time by means of Cloud & Fog computing via language to expand the scope of analytics at sensor level; wherein Fog computing provides an additional decentralized layer (store, analyze and act) and Cloud works as a fast, accessible and flexible storage system. Further to SSD and in-memory DB, storage in relation to data directly saved in memory, mixed storage architecture (with hybrid databases) is cheap in terms of IO/sec.

In some embodiments of the present invention, a method for monitoring and reporting one or more building facilities' life cycle, maintenance, and metrics audit is provided with a productive and cost-effective environment through optimization of the basic elements of the building facilities such as temperature, humidity, air flow, flue gas, Indoor Air Quality (IAQ), luminous emittance (in Lux), on the basis of open source Relational Database Management System (RDBMS), Total Cost of Ownership (TCO), with additional sensors, vision systems and IoT, IoS etc. The system may also record the rope replacement data regarding decidable maintenance, water leakage damage, adenosine triphosphate (ATP) testing, sound and heat testing which are independently separated with the elevator controller. Independent means for obtaining lift data are implemented for several systems, configured with different models or different brands, no matter whether the lift is an old version or new generation model. Under the international standard of rope and/or cable structure interface with respect to BIM, AR, Artificial Intelligence (AI), machine to machine (M2M) Network, virtual private network (VPN), there are several interfacing structures can be implemented, for example, a M2M network can be developed with the help of a VPN network. Simple data SIM cards are used for this purpose, which keeps the regular costs down.

In some embodiments of the present invention, the method for monitoring and reporting one or more building facilities' life cycle, maintenance, and metrics audit may comprise collecting, with one or more sensing modules, operation data of the one or more building facilities; receiving and storing, with one or more processors, the collected operation data; simulating, with the processers, a building information model (BIM) of the building using the collected operation data; generating, with the processers, the one or more building facilities' life cycle, maintenance, and metrics audit reports using the collected operation data; computing, with the processors, a present carbon dioxide emission of the building; predicting, with the processors, a future carbon dioxide emission of the building; and communicating, with one or more communication modules respectively connected to one of the processors, for communicating with the processors and a control center.

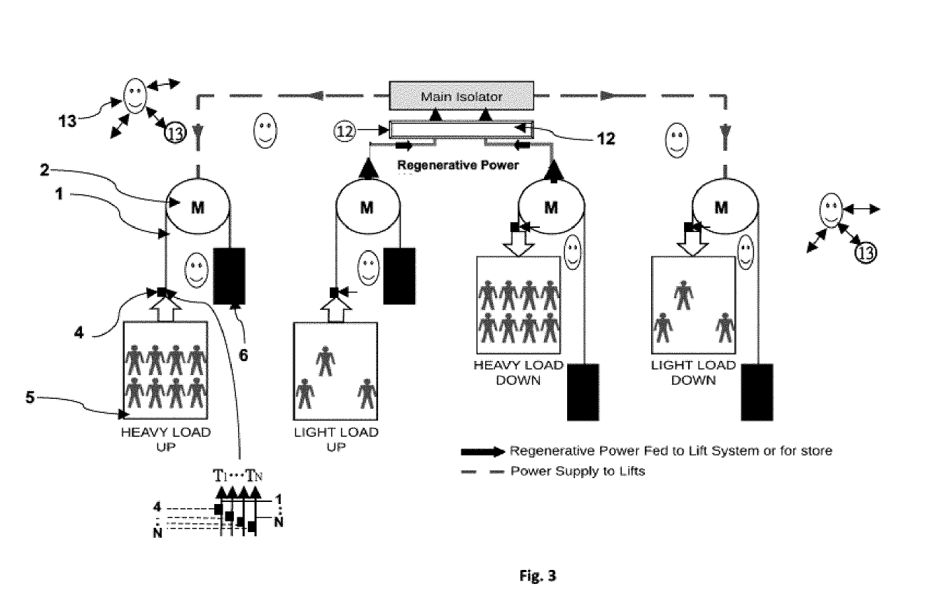

In some embodiments of the present invention, the method for monitoring and reporting one or more building facilities' life cycle, maintenance, and metrics audit may further include achieving energy efficiency improvement, on the basis of a building design model (BDM), by metering of lift power consumption as shown in FIG. 3 and measuring the building power consumption and loading to carry out a scheme for energy saving.

In some embodiments of the present invention, the method for monitoring and reporting one or more building facilities' life cycle, maintenance, and metrics audit may further comprise estimating the heat transfer between the building and external environments by calculating the overall thermal transfer value (OTTV) of surfaces of one or more exterior building walls and roofs including glass lift shafts; measuring, with one or more electrical transformers, electrical and/or voltage of the building facility's electricity consumption; storing, with one or more electricity storage stations, electrical energy regenerated in one of the building facilities; and redistributing the regenereated electrical energy into an electricity distribution network. In particular, the heat gain though glass window at a particular time, Q′_{g}, may be calculated by:

Q′_{g}=U_{f}·A_{f}·(Tₐₒ−Tₐᵢ),

where U_{f} is the heat transfer index value of fenestration, A_{f} is the area of fenestration, Tₐₒ is the outdoor air temperature and Tₐᵢ is the indoor air temperature.

In some embodiments of the present invention, the method for monitoring and reporting one or more building facilities' life cycle, maintenance, and metrics audit may further comprise taking outdoor temperature, local conditions, requirements to indoor temperature and cost-effectiveness by users into consideration to improve the energy usage efficiency. General frameworks, regulated methods for calculating overall energy efficiency of the building, and bottom-line usage standard for energy efficiency are adopted in a supervisory control and data acquisition (SCADA) system for constructing new buildings or renovating existing buildings.

In some embodiments of the present invention, the method for monitoring and reporting one or more building facilities' life cycle, maintenance, and metrics audit may further comprise taking the Overall Thermal Transfer Value (OTTV) of the building wall surfaces of the same orientation, weather and sun data into consideration as the three major components for thermal gain. The OTTV for heat transfer via non-transparent surface and glass surface may be used to estimate overall thermal conductivity of the glass lift shaft (or exterior layer of the building). It can be noticed from the records of electricity usage of the glass lift shaft that the huge electricity usage is mainly caused by the use of cooling equipment.

In some embodiments of the present invention, the method for monitoring and reporting one or more building facilities' life cycle, maintenance, and metrics audit may further comprise taking different absorption of solar-energy by building walls of different orientations in account. Firstly, respective OTTV of building wall of each orientation is calculated, and then the weighted average of calculated values are obtained. Finally, the overall OTTV of all building walls are calculated.

In some embodiments of the present invention, the method for monitoring and reporting one or more building facilities' life cycle, maintenance, and metrics audit may include similar methods used for calculating the OTTV of building roofs. The calculation of OTTV of building roofs would be simpler as the roofs are usually without large area of glasses (except for some courtyard located in the middle of the building). Although OTTV is mainly used for evaluating overall thermal conductivity of exterior layer of the building. The formula obtained with three parameters: the equivalent temperature difference (TDeq), the temperature difference between exterior and interior designconditions (DT) and the solar factor for that orientation (SF) by large determine the accuracy in energy consumption evaluation by using OTTV as well as reflect what types of problems exist.

In some embodiments of the present invention, the method for monitoring and reporting one or more building facilities' life cycle, maintenance, and metrics audit may further comprise calculating the indexes for evaluating the overall thermal conductivity of glass lift shafts or exterior layer of the building, TD and SF, with heat conduction and solar radiation on the non-transparent surface as well as the glass surfaces. Potential energy saving can be calculated and applied in the fields of data-collecting networks, energy collection, deep learning and environmental technologies.

In some embodiments of the present invention, the method for monitoring and reporting one or more building facilities' life cycle, maintenance, and metrics audit may further comprise evaluating the thermal gain of glass lift shaft from outdoor to indoor, through heat conduction of exterior layer of the building, including OTTV, heat dissipated from air conditioners, heat generated by lifts and control systems.

In some embodiments of the present invention, the method for monitoring and reporting one or more building facilities' life cycle, maintenance, and metrics audit may further include maximizing the effectiveness of power consumption. It is essential to identify as much as possible underlying operational problems of the building, the improvement and optimization opportunities during investigation and reliable enough for energy gap identification.

In some embodiments of the present invention, the method for monitoring and reporting one or more building facilities' life cycle, maintenance, and metrics audit may further include converting, with one or more photovoltaic solar electricity generation units, solar energy into electrical energy; wherein the photovoltaic solar electricity generation units comprise one or more building windows and building glass wall coated with transparent photovoltaic material and electrically connected to the electricity storage station.

In some embodiments of the present invention, the method for monitoring and reporting one or more building facilities' life cycle, maintenance, and metrics audit may further include converting, with one or more solar thermal-energy exchange units, solar energy into electrical energy; wherein solar thermal-energy exchange units comprise one or more building windows coated with transparent thermal absorbing material and connected to a thermal-electricity conversion layer; wherein the thermal-electricity conversion layer is a piezoelectric coating on the coated building window electrically connected to the electricity storage station.

In some embodiments of the present invention, the method for monitoring and reporting one or more building facilities' life cycle, maintenance, and metrics audit may further include maintaining an effective working environment which is run automatically and comprehensively, and flexible enough to adapt to future changes in the needs of the working environment.

In some embodiments of the present invention, the method for monitoring and reporting one or more building facilities' life cycle, maintenance, and metrics audit may further include computing and investigating the collected building documentation but not limit to the items listed out inthe present disclosure. Basic information is recorded during quality audit of maintenance work factors such as:

a) file no., b) building name, c) address, d) date of installation, e) no. of floors, f) floor served, g) lift manufacturer, h) maintenance company, i) lift type, j) lift number, k) location of m/c, l) rated load, m) machine model, n) disable lift, o) fireman lift p) door open size, p) door type, etc., q) c.p. model, s) no. of ropes, t) roping (1:1 to n:1), u) rope diameter, v) normal load q, w) car mass f, x) wire rope type, y) nominal strength, z) rope diameter, aa) number of bending, bb) speed, cc) diameter of traction sheave, dd) diameter of deflection sheave, ee) rope bending length, ff) the acceleration, and gg) other environment factors.

In some embodiments of the present invention, the method for monitoring and reporting one or more building facilities' life cycle, maintenance, and metrics audit may further include maximizing the building operation improvement, the data collection is carried out throughout the year so that the operation parameter trends in cool and hot seasons as well as intermediate seasons can be fully examined Underlying operational problems would occur for diagnostic monitoring and functional testing.

In some embodiments of the present invention, the method for monitoring and reporting one or more building facilities' life cycle, maintenance, and metrics audit may further include conducting initial equipment and devices checking, simple fixing of systems, such as calibration of sensors, so as to increase the effectiveness of the diagnostic monitoring and testing, and facilitate the understanding the root causes of operational issues.

In some embodiments of the present invention, the method for monitoring and reporting one or more building facilities' life cycle, maintenance, and metrics audit may further include performing energy modeling and simulation for the building based on building information.

In some embodiments of the present invention, the method for monitoring and reporting one or more building facilities' life cycle, maintenance, and metrics audit may be related to energy modeling which can: (a) evaluate accurately the detailed breakdown of energy use for the building; and (b) evaluate the amount of energy saving to help in selecting the identified opportunities.

In some embodiments of the present invention, the method for monitoring and reporting one or more building facilities' life cycle, maintenance, and metrics audit may further include developing plan to summarize all the findings, such as building current operating information; building annual energy use and its breakdown, in planning stage and plan the subsequent activities for optimizing the existing building facilities' life cycle.

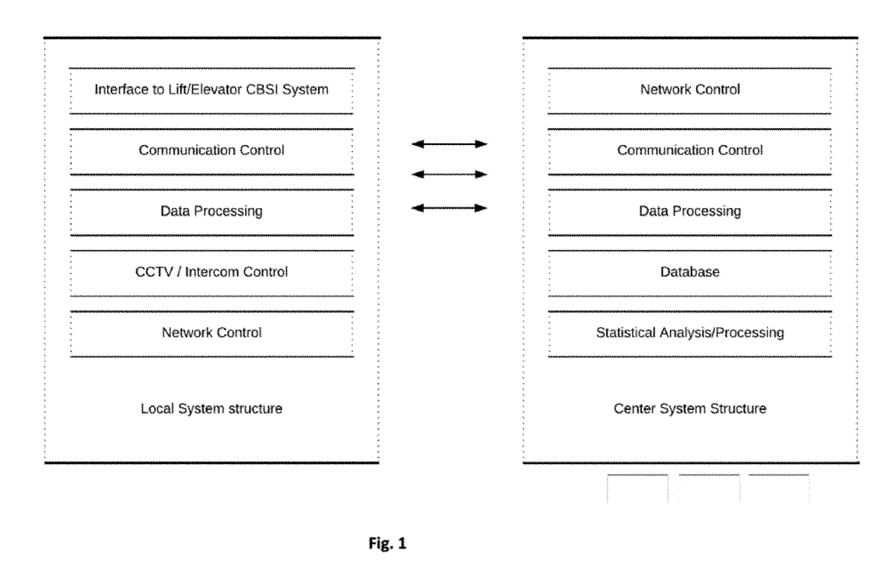

FIG. 1 is a block diagram in accordance with the data operation and configuration of one embodiment of a system for monitoring and reporting one or more building facilities' life cycle, maintenance, and metrics audit, illustrating data acquisition, analytics, processing, communication, overview running mode and interface of the systems.

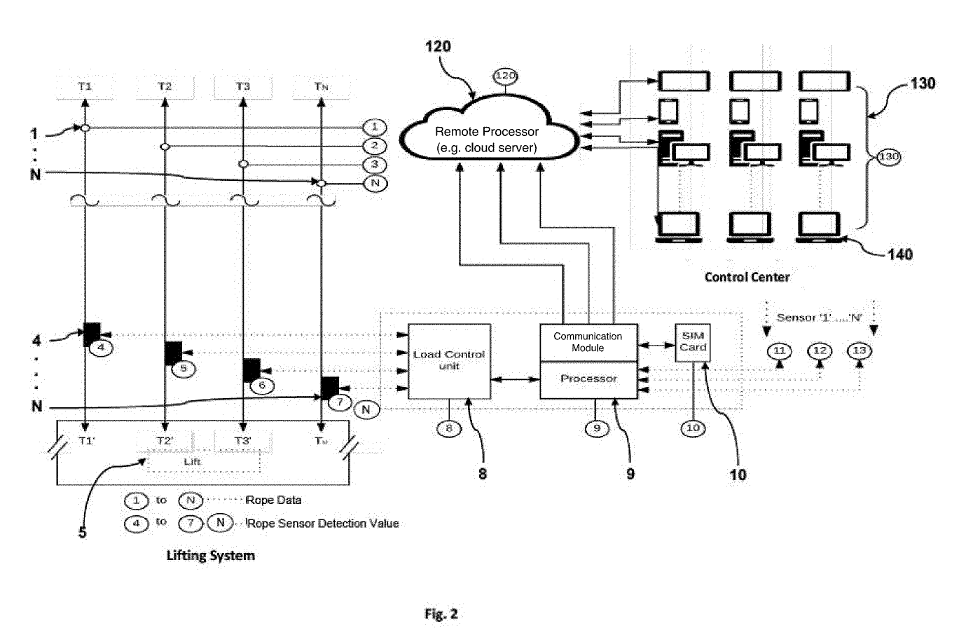

FIG. 2 illustrates one embodiment of a system for monitoring operations of a lifting system comprising one or more lifts 5 and one or more counterweights 6. In this embodiment, the system comprises one or more load sensors 4, each installed on a suspension means or lifting equipment 1, for collecting lift operation data such as cable tension profile, power consumption and loading of the lift 5; wherein the suspension means comprises one or more ropes, cables and one or more tracking pulleys; a load control unit 8 for controlling the movement of the lifts 5; a processor 9, electrically connected to the load control unit 8, for executing an optimization process to optimize the load distribution in the suspension means 1 and power consumption of the lifts 5; one or more remote processors 120, such as cloud server, for receiving and storing the lift operation data; a communication module being connected to the processor 9 for communicating with the remote processor 120 and a control center system 130; an the control center 130 including on or more network user interfaces 140, for accessing and retrieving data from the remote processor 120. The operation data generated by the load sensors 4 are sent to and collected by the remote processors 120; wherein the remote processors 120 are further configured to analyze the collected operation data for detection of abnormal operation, including excessive wear in the suspension means 1 or lift equipment and fatigue in the ropes and cables, of the lifting system; and wherein the remote processors 120 are further configured to generate a Lift Maintenance and Measure Audit Report (LMAR) from the collected operation data.

In some embodiments of the invention, the system for monitoring operations of a lifting system further comprises a plurality of noise sensors for collecting noise data for determination of the load distribution evenness of the cables in the suspension means 1; wherein at least one of the load sensors 4 is integrated with a wired or wireless transmitters for transmitting the lift operation data to the load control unit 8; wherein at least one of the noise sensors is integrated with a wired or wireless transmitter for transmitting the noise data to the load control unit 8; and wherein the load control unit 8 is integrated with a wired or wireless transceivers for receiving lift operation data from the load sensors or noise sensors and transmitting control signals to the remote processors 120 for audit control.

In some embodiments of the present invention, the load sensor 4 may be various type of detect sensors with controller. However, similar sensor available in the market can also be used to execute—the remote monitoring system accordingly. Data of lift (elevator) and/or escalator or similar equipment status will be collected by installed sensors, and transmitted to internet. The collected data of individual lift (elevator) will be stored in an internet database.

FIG. 3 illustrates different running modes of a lifting system in one embodiment of the invention. The suspension means 1 may comprise ropes or cables being driven by a lifting machine located at a high position. Currently, the lifting machine may include, in its simplest form, one or more electric motors or electric drives 2 for actuating movements of the lifts 5, worm screw reducers and drums which ropes roll round during upward movement of the lifts 5 and ropes unroll during downward movement of the lifts 5.

In some embodiments of the present invention, the lifting system may further comprise connected devices, such as flexible cables under the lifts 5 and traction pulleys connected to the electric drive or motor 2 for dragging the ropes by fiction. As it can be easily appreciated that such configuration can greatly reduce the work load of the lifting machine.

Depending on the movement direction and loading conditions, the lifting system may have running modes, namely, “HEAVY LOAD UP”, “LIGHT LOAD UP”, “HEAVY LOAD DOWN” and “LIGHT LOAD DOWN” as illustrated in FIG. 3. These four running modes are configured with roping ratio of 1:1 in the illustrated embodiment. However, it would be appreciated by ordinary skilled in the art that there may be various kinds of roping ratios such as 1:1; 2:1; . . . ; N:1 etc., with N nos. in various kinds of lifting systems at different running modes, where N is an integer.

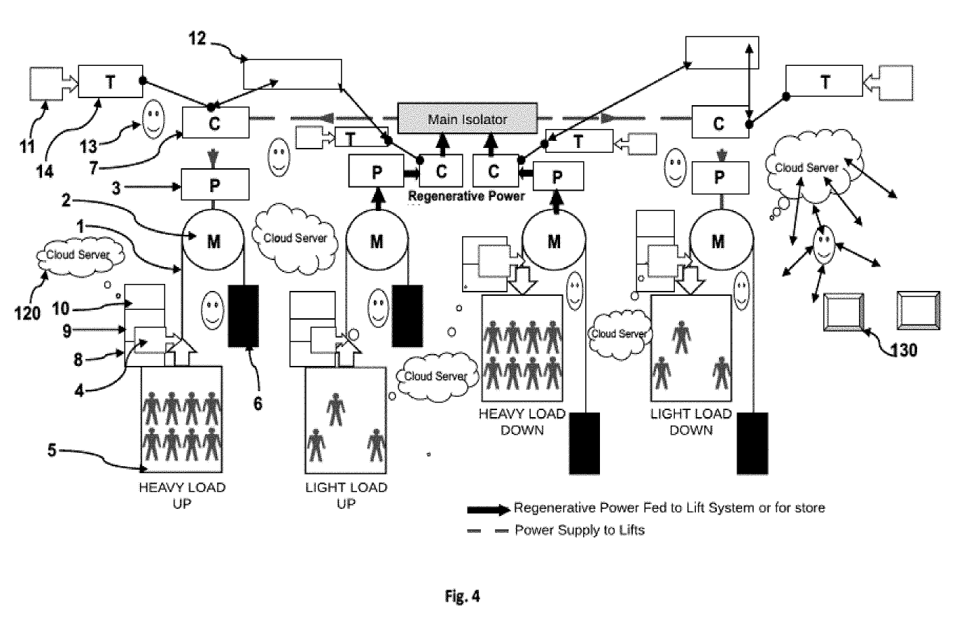

Referring to FIG. 4, the system for monitoring operations of a lifting system may further comprise one or more regenerative energy storage assemblies 12 for storing the electrical energy regenerated during movement of lifts 5 and/or counterweights 6 and feeding the stored electrical energy into the lifting system, electricity distribution network, and a main isolator.

The aforesaid system may further include one or more metering devices 11, each interfaced with a load sensor 4; one or more electrical power supplies 7, being interlinked with a plurality of motor control panels 3 and the regenerative energy storage assemblies 12.

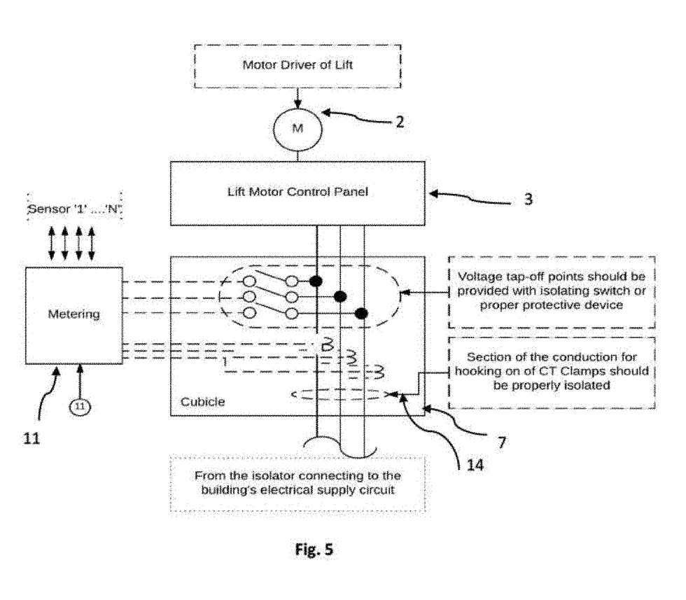

As shown in FIG. 5, the aforesaid system may further comprise one or more isolating switches, each respectively connected to one of the regenerative energy storage assemblies 12 installed between a motor control panel 3 and an electrical power supply, for allocating currents to the electric drives according to the power consumption of the lifting system measured by the load sensors; and a section of the conduction for hooking on of CT Clamps 14 for interfacing with the metering devices 11.

In some other embodiments of the present invention, the system for monitoring operations of a lifting system may adopt generators made of permanent magnets and copper coils to regenerate electrical energy, recycle the regenerative energy for effective energy saving. Said system can be used in various types of transporting or similar facilities, to ensure energy consumption needs of the systems are met and allow excess energy to be further recycled to be new energy in carbon trading.

Referring to FIGS. 3 and 4, the system for monitoring operations of a lifting system may further comprise a plurality of optical intelligent systems 13 for capturing the lift movements and passenger flow for simulating the lift cars' flights, which may be installed at lift shafts, lift machine rooms and lift equipment or any other locations in or out of the building. The optical intelligent systems 13 may comprise inertial or non-inertial cameras, for animating and tracing the elevating trips of the lift cars, and 3D cameras for recording flow of passengers in the lifting system. The simulation of the lift cars' flights for arranging lift zoning in which the building floors are divided into a plurality of clusters of stops each to be served by one or more of the lift cars. With this lift zoning arrangement, passengers that travel to a particular floor have a higher chance of being grouped together such that the efficiency of the traffic as well as the energy usage can be improved.

In some other embodiments of the present invention, the optical intelligent systems 13 may be in the form as cameras in adapt with smart phones which enable user identification via the smart phones and provide a recording capability of still images and videos of users, objects, building, equipments and things. By providing a wireless network connection via internet to view and talk with a user and or an auditor via a phone from anywhere. Still image and/or video storing capabilities may also be provided to upgrade security to the next level. High definition (HD) quality display with more vivid image display may be enabled with LCD displays. The view port configuration and target can be selected. Next step is viewports navigation control and creation of 3D models via specific computer programs including, but not limited to, building models in 3D Max using AutoCAD plans. The following steps may include setting viewport layout sample modeling, material and maps, modeling in detail, lighting and camera via process zoom functions, perspective and orthographic viewport controls together in computing with metering devices 11 and regenerative energy storage assemblies 12.

In some other embodiments of the present invention, the system for monitoring operations of a lifting system may further comprise a plurality of door sensors, being installed in the lifts, for detecting whether doors of the lift cars are opened or closed; and a plurality of hoist brakes and braking means, wherein each of the hoist brake or braking means is urged to hold a lift car when the door sensor in the lift detects that the doors of the lift is opened.

In some other embodiments of the present invention, the system for monitoring operations of a lifting system further comprises a plurality of fire or smoke sensors, being installed in a plurality of lift shafts and building facilities for detecting the presence of a fire and transmitting the detected signals to the load control unit 8 when the presence of fire is detected; a fire alarm system; wherein the load control unit automatically initiates the fire alarm operation; and wherein the fire alarm system operation comprises moving the lift cars to a safety floor when the fire detection signal is received.

In some other embodiments of the present invention, the fire alarm system includes a plurality of ventilation ports being located above at least one of the lift shafts, wherein at least one of the ventilation ports is installed with a solar thermal-energy exchange window; wherein the solar thermal-energy exchange window is closed for energy generation under normal condition and caused to open for ventilation when the presence of fire is detected.

In some other embodiments of the present invention, the fire alarm system further includes a plurality of buttons, being located at stairs and/or corridors of the building; wherein the load control unit are triggered to initiate the operation of the fire alarm system; and wherein the fire alarm system operation comprises moving the lift cars to a safety floor, which would be the first floor where the main entrance is located, when one of the buttons is pressed.

In some other embodiments of the present invention, the system for monitoring operations of a lifting system may further include sensors or detectors such as electrical, magnetic, mechanical, optical, acoustic, haptical, mechanical, bioactuators, etc., integrated with controllers, making use of various of telecommunication technologies such as 3G/4G/5G Cellular, NB-IoT, LoRa, Sigfox, for generating data, detecting patterns, increasing forecastability, improving decision making and performing monitoring communication in various fields.

In some other embodiments of the present invention, the system for monitoring operations of a lifting system may further interface with electrical cable carrier communication networks such as PLC and poLine, use the exiting electrical cable as communication media to avoid investment in wire communication so as to reduce cost of the system and save energy.

In some other embodiments of the present invention, the system for monitoring operations of a lifting system may further connect with 3D Time of Flight (TOF) or other sensor connection means with similar functions, cope with clearance measurement equipments for traction elevator doors to design and do functional analysis on various systems.

In some embodiments of the present invention, the system for monitoring operations of a lifting system may be used for dynamic tolerance analysis modelling of the lift balance formats with no-load and full-load at up/down movements. At different running modes, via various type of detect sensors, such as electrical, magnetic, chemical mechanical, optical, acoustic, haptical, mechanical, bio-actuators, salt, acid etc.

Referring back to FIG. 2, the use of load sensors 4 on rope and/or cable, the load control unit 8 integrated with long distance wire/wireless data transmission device enable auditor to conduct effective auditing process, predictive analysis and quantifying of the life of detected equipment. Substantial machine learning is realized with the processor 9 communicating between load sensors 4, load control unit 8, cellular module and a SIM card 10. Automatic communication to remote processor 120 and control center 130. So it is not necessary to obtain the load data as in prior arts from the elevator controller communicating with load sensor on the lift car, so the present invention is more advanced and fundamentally different from prior art which based on getting the data from the elevator controller thereof. In the present invention, the communication module is connected with Subscriber Identification Module (SIM) card 10 which is an integrated circuit portable memory chip intending to securely store the international mobile subscriber identity (IMSI) number and its related key is used to identify and authenticate subscribers on mobile telephony devices (such as smart phones and computers). Therefore, the system for monitoring operations of a lifting system of the present invention may be applied in various types of lift and escalator/passenger conveyors, mechanical car-parking system and similar function apparatus.

In some embodiments of the present invention, the system for monitoring operations of a lifting system may also be applied with information and machine learning technologies to form a Smart Network interfacing with Smart Internet of Things (IoT), Smart Internet of Services (IoS), Smart Internet of Everythings (IoE), Smart Internet of Vehicles (IoV), big data & hadoop to processing data such as information of weather on air, forecast, humidity . . . etc., be provide by the Observatory. With the use of mobile devices, smart phone applications may be used to control data flow and where it is remotely stored, with collective intelligence, map reduction, eventual consistency, and predictive analytics. The system may further includes software programs for calculation of mechanical characteristics of ropes/cables, maintaining and protecting a central database. It shall be appreciated that there are several formula models for such purposes and various algorithms to handle different features. In one embodiment, an algorithm for an analytical study on fatigue failure of main ropes in lift build modeling of roping ratio 2:1 is used to obtain a new simultaneous means of non linear lift loading on the ropes during starting-up and acceleration. Regarding total tension and maximum pressure point where car cage is parked at lowest floor and counterweight is placed at upper level, well-established formula for calculation of the loading on the rope, Fc, is:—

Fc=(Wcar+Q+Wrope+Wcable)×(g+a)+Total jv/R0
Where,
Wcar is the weight of the lift 5;
Q is the rated loading (rated handle capacity) of the the lift 5;
Wrope is the weight of rope;
j is the rotational inertia of a below sheave calculation of detected rope
Wcable is the weight of travelling cable;
a stands for acceleration of the lift (rope);
g stands for acceleration due to gravity;
v is the rotational start up angle;
R0 is the radius of traction sheave.

In some embodiments of the present invention, the lifts 5, the counterweights 6, the power supplies 7, and the load control unit 8 are basic elements needed to make a rope/cable or similar system. The system may further include load support and suspension means which may be rope and/or cable suspension (dead point) with elastomeric spring buffers or adjustable compression springs. Therefore, programmable measurement control can be installed to receive the signal from the rope sensors and convert them into useable data for measuring important parameters for ropes such as the relatively large axial load in comparison to bending and torsional loads which can easily viewed. Further, the ropes under bending and tensile stresses, force and torque related tensions can be audited and adjusted in real time according to the record and report. With similar force measurement means, the following parameters may be to obtained: a) tensile forces, b) number of bending cycles, c) corrected of bending cycles, d) number of working cycle, e) loading sequence bending length, f) load elements per load sequence. Further, there are five dimensioning limits for rope drives (with reference to Feyrer (2007)) such as: i) Rope working cycle, ii) Donandt force, iii) Rope safety factor, iv) discarding number of wire breaks, v) optimal rope diameter etc. Also, real time measurement of power at different running modes of lifts operation for dynamic tolerance analysis of the lift of different loading conditions (no-load, lightly-loaded or heavily-loaded) can be achieved via input of Sensor ‘1’ . . . ‘N’ as shown in FIG. 2. Based on the analysis results, preventive/predictive maintenance can be scheduled. In particular, regarding acceleration calculation, one of well-established formulas for detecting load weighting value is:

Vector K=Vector N(G1+G2)/2Q
Where:
K is the lift balance coefficient;
N is the roping ratio;
G1 is the weight difference between the lift 5 and the counterweight 6 less the maximum fiction coefficient of the system;
G2 is the weight difference between the lift 5 and the counterweight 6 plus the maximum fiction coefficient of the system;
Q is the rated loading (rated handle capacity) of the lift 5.

In some embodiments of the present invention, the system for monitoring operations of a lifting system may be further connected with wire and/or wireless communication system via cellular module of different class, dual band of a specific range, interface module, General-purpose input/output (GPIO), Internet protocol supported printer, plotter and/or similar equipments to assist responsible persons to engage lift maintenance audit, overview running modes, data analytics (include but not limit to descriptive analytics, diagnostic analytics, predictive analytics, prescriptive analytics); wherein similar function and several analysis can be applied to calculate, for example, simple bending and reverse bending, as rope bend, even drive, defection and break are major factors to quantify the lifetime of a rope and/or cable that is roved over a sheave for lift operation. The system may be used to process the number of bending cycles of rope as it is necessary to know the effective rope tensile force S as precisely as possible. If no more precise information is available, the effective rope tensile force S for lifting appliance can be evaluated from a) the load Q, b) the number of bearing wire ropes nT, c) the acceleration g due to gravity and d) the global rope force factors fs1, fs2, fs3 and fs4, friction from the load guidance (such as sliding guidance, rope efficiency, parallel bearing ropes, acceleration, deceleration, load speed), a well-established formula calculating the effective rope tensile force, S, is:—

S=Q×g/nT×fₛ₁×fₛ₂×fₛ₃×fₛ₄

In some embodiments of the present invention, a database interfacing with imaging system of still image and/or video storing capabilities is also provided to upgrade security to the next level. High Definition (HD) quality display and more vivid image display are enabled via LCD application. It enables user and/or auditor identification via phones and provides a recording capability of still images and video of any object and/or person for credible audit of lift operation, such as loaded and unloaded operation in real time. Various types of vision and audio sensors such as 3D cameras with a controller and integrated long distance wire/wireless data transmission device are implemented to form a multi/independent, remote reporting maintenance, audit and measure system which can easily check the lift shaft. The controller may include a control interface circuit comprising a general packet radio servie (GPRS) module, wifi, Bluetooth, 3G, 4G(LTE), 5G, Z-wave, NFC, IEEE 802,15.4 (Zigbee), Ethernet interface circuit and extending to LoRa, Sigfox, Narrowband (NB)-IoT, Internet Protocol (IP) Signaling Systems-Advanced Intelligent Networks (AIN) system etc.

In some embodiments of the present invention, it can also be provided with a map database, whereby a Cellular or Communication and Transmission System (CTS) is accessed by a local system. A map indicating geographic and other necessary information in locating the lift site is displayed. The map database is possible to be linked to a Total Maintenance Management System (TMMS). It may relate to but not limit to NosQL, languages, web oriented/JSON, Implicit scheme and support large amount of data, eventual consistency, open source etc. The system may further connected with 3D Time of Flight (TOF) or similar sensors to expand the scope of structural flexibility. It may also adopt a risk based model for fault call record, breakdown check, car landing check, door clearance and leveling measurement, rope condition check by accessing the lift operation, guide shoe situation, guide rail situation, traction sheave situation, vibration. The method is communicate from the rope suspension and input details such as Normal load Q, Car mass F, Wire rope type, Nominal strength R, rope diameter d, number of bending N, rope bending length L, Diameter of traction SheaveDₜ, Diameter of deflection Sheave Dᵣ, Speed V for predictive analytics several formula models can apply, one of them such as obtain Simple Bending and Combined Fluctuating Tension and Bending With the constant tensile forces S and the number of simple bending cycles and the number of combined fluctuating tension and simple bending cycles for embedment the Claims as calculation as:

lg N=b0+(b1+b3×lg D/d)×(lg S/d²−0.4×lg R0/1770)+b2×lg D/d+lg fd+lg fC

In some embodiments of the present invention, a method for monitoring operations of a lifting system is provided for conducting diagnostic monitoring of lift and escalator installation and logging lift power during peak hours and non-peak hours for trending analysis.

In some embodiments of the present invention, the method for monitoring operations of a lifting system may include analyzing the collected trend logged data, measuring lift power consumption during a designed specific period. The ratio of lift power consumption during a designed specific period is plotted. This ratio is lowered down when it is found to be relatively high so as to save energy. The regenerating power is stored via a series of store battery banks and/or capacitors.

In some embodiments of the present invention, the method for monitoring operations of a lifting system may further include minimizing wear due to uneven setting of the rope tensions of hoisting rope in order to increase safety factor and limit wear and tear, making use of systems held in elevator installation with various load distributions in the rope set during the ride which can be adjusted optimally.

In some embodiments of the present invention, the method for monitoring operations of a lifting system may further include investigating of incidents such as uncontrolled movement, sudden falling or similar complaints via remote auditing. Regarding running environment and quality, parameters such as stress, tension, suspension, vibration, frequency, force equalization etc. are considered in calculation of the lifetime of ropes or cables, such thatthe ropes or cable which are always have a limited lifetime can be replaced well before their failure, and related elements based on all related rope and/or cable data. With regards to lift equipment's other parts such as groove, sheave, pulley, gear and shaft, which resist relatively large axial load in comparison to bending and torsional loads, the collecting of data can be carried out from the lift to overcome the friction of the first starting due to the mechanical efficiency of the shaft, pulley, guide shoes, etc., (force factors fₛ₁ . . . fₛ₄), and friction from the load guidance. The LMAR may also credibly predict the lifetime affected by the friction and the performance of the lift operation.

In some embodiments of the present invention, the method for monitoring operations of a lifting system may further include measuring how power consumption is affected, besides the load, by the unbalanced load to move, regeneration of electrical power, and storage and reuse of the regenerative power, such that energy management entities can monitor, measure, and control their electrical building loads. The method may further provide metering, sub metering, and monitoring functions that allow facility and building managers to gather data to make more informed decisions about energy activities across their sites according to (a) energy management system (ISO 50001), (b) environmental management system (ISO 14001), (c) information security management system (ISO/IEC 27001). The methodmay also used in stimulating technological innovation and economic growth with the flexibility required to exchange CO₂ cap-and-trade (C&T) emissions trading program in a wholesale electricity prices market-based approach for controlling pollution by providing economic incentives for reduction of emissions, achieving lowest cost to society, notably for mitigating climate change.

In some embodiments of the present invention, the method for monitoring operations of a lifting system may further include auditing the sum of basic elements defining the shaft efficiency, measuring the quality of lift installation and predicting the power dissipated through the aerodynamic resistance (proportional to the square of the rated speed) produced during the lift operation, based on the fact that the higher the shaft efficiency is, the lower the energy that is dissipated due to friction.

The system and method for monitoring operations of a lifting system may be integrated with technologies of Virtual Reality (VR), Augmented Reality (AR), Mixed Reality (MR), Substitutional Reality (SR) or Cinematic Reality (CR) to improve and minimize the effect of errors, labour & safety problem associated with existing lifting systems which require manual monitoring and inspection. VR, AR, MR or SR based mobile device demonstration system for machinery may be applied in procedural tasks in diagnostic and maintenance. It is a live direct or indirect view of a physical, real-world environment whose elements are augmented (or supplemented) by computer-generated sensory input such as sound, video, graphics or GPS data. The technology is available to users by related tool, which give users valuable and additional information of equipment and processes, guide them in performing operational tasks and allow them to work hand-free, which is economical to get an maintenance and audit report quickly and safely, mitigate risks of working in lifts.

Whereby co-operation with independent mechanical rope gripper be used as stopping element of untended car movement protection (UCMP). Further, focusing on existing Lift E-platform reporting systems also cannot provide data analysis process, deep learning, 24 hour-7 day data mining Whereas by further applying and integrating (BIM) Building information modeling system, a digital representation of physical and functional characteristics of a facility can be achieved. Knowledge, resource and information about a facility forming a reliable basis for making decisions, during its life-cycle from conception to demolition, in Enterprise Resource Planning (ERP), Retro-commissioning (RCx), Energy Audit (EAC). Therefore, cost-effective systematic process is provided to periodically check an existing building's performance and identify operational improvements for save energy and lower costs.

In some embodiments, the sensing modules of the system may further comprise a three-dimensional space measuring sensor installed inside and outside the building for collecting building geographic construction data.

In some embodiments, the sensing modules of the system may further comprise one or more fire sprinkler hose retractor button for collecting fire sprinkler hose retractor data and transmitting the data to the control center for integrating a fire extinguishing tracking data system.

In some embodiments, the sensing modules of the system may further comprise an energy measuring device, in communication with the sensing modules, for measuring energy consumption of building equipment; wherein the processor is configured to receive energy consumption data of the building equipment from the energy measuring device; and simulate a energy consumption model of the building for developing a building equipment operation optimization plan.

In some embodiments, the sensing modules of the system may further comprise one or more air index sensors, each installed in one of the one or more building lift shafts for collecting air index data; and one or more microbial sensors for collecting and monitoring disease spread data of the elevator shaft and transmitting the disease spread data to control center for integrating a disease spread data tracking system.

In some embodiments, the sensing modules of the system may further comprise one or more garbage and kitchen energy storage conversion sensors for collecting and monitoring waste and kitchen energy storage data of the building and transmitting the data to the control center for integrating a garbage and kitchen waste energy storage tracking and data system.

In some embodiments, the sensing modules of the system may further comprise one or more regenerative energy sensors for collecting and monitoring regenerative energy data of the building, and transmitting the data to the control center for integrating a regenerative energy storage tracking and data system.

In some embodiments, the sensing modules of the system may further comprise one or more regenerative energy sensors for collecting and monitoring regenerative energy data of the building, and transmitting the data to the control center for integrating a regenerative energy storage tracking and data system.

In some embodiments, the sensing modules of the system may further comprise one or more endothermic pressure layer conversion sensors for collecting and monitoring the endothermic pressure layer energy storage data of the building, and transmitting the data to the control center for integrating an endothermic pressure layer energy storage tracking and data system.

In some embodiments, the sensing modules of the system may further comprise one or more solar thermal absorption coating conversion sensors for collecting and monitoring the solar thermal absorption coating energy storage data of the building and transmitting the data to the control center for integrating a solar thermal absorption coating energy storage tracking and data system.

In some embodiments, the sensing modules of the system may further comprise one or more electroplating film thermal energy absorption coating conversion sensors for collecting and monitoring electroplating film thermal energy absorption coating energy storage data of the building and transmitting the data to the control center for integrating a electroplating film thermal energy coating energy storage tracking and data system.

In some embodiments, the sensing modules of the system may further comprise one or more anodized film thermal energy absorption coating conversion sensor for collecting and monitoring anodized film thermal energy absorption coating energy storage data of the building and transmitting the data to the control center for integrating a anodized film energy storage tracking and data system.

In some embodiments, the sensing modules of the system may further comprise one or more vacuum deposition thermal energy absorption coating conversion sensors for collecting and monitoring vacuum deposition thermal energy absorption coating energy storage data of the building and transmitting the data to the control center for integrating a vacuum deposition energy storage tracking and data system.

In some embodiments, the sensing modules of the system may further comprise one or more solar selective absorption coating sensor for collecting and monitoring solar energy selective absorption coating energy storage data of the building and transmitting data to the control center for integrating a solar selective absorption coating energy storage tracking and data system.

In some embodiments, the system may further comprise a central device for accessing a cloud server by means of SSL, or HTML convergence, a centralized access platform (Masslink), and a connected network user interface to form an intelligent system.

In some embodiments, the system may further comprise: one or more cameras, installed in a lift shaft or a lift car in the lift shaft of the elevator, for capturing videos or images of the lift car or lift shaft; an elevator controller for controlling the lift car; and an unintended car movement protection (UCMP) unit comprising a mechanical rope gripper wherein the one or more processors are further configured to receive the captured videos or images of the lift car or lift shaft from the camera; process the received videos or images and detect, using artificial intelligence, abnormal incidents happening inside the lift car or lift shaft; and transmit an emergency call to the control center and an emergency instruction signal to the elevator controller or the UCMP unit when one or more abnormal incident is detected.

The abnormal incidents may include: abnormal human body movements or gestures which are suspected to be caused by criminal actions or fatal accidents; unintended opening or close of lift door; over-speeding of the movement of the lift car; unintended movement of the lift car; breaking of cables in suspension means connected to the lift car; and existence of one or more obstacles in movement path of the lift car; and the emergency instruction signal sent to the elevator controller may include any one or a combination of: stopping the lift car immediately with the UCMP unit; moving the lift car to a safety floor; and activating an alarm in the lift car.

The embodiments disclosed herein may be implemented using general purpose or specialized computing devices, mobile communication devices, computer processors, or electronic circuitries including but not limited to digital signal processors (DSP), application specific integrated circuits (ASIC), field programmable gate arrays (FPGA), and other programmable logic devices configured or programmed according to the teachings of the present disclosure. Computer instructions or software codes running in the general purpose or specialized computing devices, mobile communication devices, computer processors, or programmable logic devices can readily be prepared by practitioners skilled in the software or electronic art based on the teachings of the present disclosure.

In some embodiments, the present invention includes computer storage media having computer instructions or software codes stored therein which can be used to program computers or microprocessors to perform any of the processes of the present invention. The storage media can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the following claims and their equivalence.

1. An interactive system for monitoring and reporting one or more building facilities' life cycle, maintenance, and metrics audit, comprising:
one or more sensing modules for collecting operation data of the one or more building facilities;
one or more processors configured to:
receive and store the collected operation data;
simulate a building information model (BIM) of the building using the collected operation data;
construct a three-dimensional model of the building using the collected operation data;
generate the one or more building facilities' life cycle, maintenance, and metrics audit reports using the collected operation data;
compute a present carbon dioxide emission of the building; and
predict a future carbon dioxide emission of the building;
one or more communication modules, each electrically connected to one of the processors, for communicating with a control center; wherein
the control center comprising one or more networked user interfaces, for accessing and retrieving data from the processors and one or more data tracking systems for automatic, intelligent, remote report re-test and retro-commissioning (RCx).

2. The interactive system of claim 1, wherein the sensing modules further comprise:
one or more three-dimensional space measuring sensors installed inside and outside the building for collecting building geographic construction data.

3. The interactive system of claim 1, wherein the sensing modules further comprise
one or more load sensors, each installed on a suspension means in at least one of the buildings' lifts for collecting lift operation data comprising cable tension profile and loading of the buildings' lift; and
one or more noise sensors, each installed on a suspension means in at least one of the buildings' lifts for collecting noise data for determination of the load distribution evenness of the cables in the suspension means.

4. The interactive system of claim 1, wherein the sensing modules further comprise one or more elevator sensors, each installed on a suspension means in at least one of the buildings' lifts for collecting the operation data of the elevator, interacting with one or more users and combining media using Virtual Reality (VR), Augmented Reality (AR), Mixed Reality (MR), Substitutional Reality (SR) or Cinematic Reality (CR) technologies to enhance the current reality vision and information.

5. The interactive system of claim 1, wherein the sensing modules further comprise:
one or more fire or smoke detectors, each installed in one of the one or more building lift shafts, for detecting presence of fire and transmitting a fire detection signal to the load control unit when the presence of fire is detected;
a fire alarm system;
wherein the fire alarm system operation comprises moving the lift cars to a safety floor when the fire detection signal is received and operating one or more of water pumps, drainage pumps and sewage pumps, fire pumps under the lift shafts;
wherein the fire alarm system comprises:
one or more ventilation ports located above the lift shafts, wherein the ventilation ports are caused to be opened when there is the presence of fire is detected.

6. The interactive system of claim 1, wherein the sensing modules further comprise:
one or more fire sprinkler hose retractor buttons for collecting fire sprinkler hose retractor data and transmitting the data to the control center for integrating a fire extinguishing tracking data system.

7. The interactive system of claim 1, further comprising:
an energy measuring device, in communication with the sensing modules, for measuring energy consumption of building equipment;
wherein the processor is configured to
receive energy consumption data of the building equipment from the energy measuring device; and
simulate a energy consumption model of the building for developing a building equipment operation optimization plan.

8. The interactive system of claim 1, the sensing modules comprise:
one or more air index sensors, each installed in one of the one or more building lift shafts for collecting air index data; and
one or more microbial sensors for collecting and monitoring disease spread data of the elevator shaft and transmitting the disease spread data to control center for integrating a disease spread data tracking system.

9. The interactive system of claim 1, further comprise:
one or more electrical transformers, each installed in an electrical power circuit of one of the building facilities for measuring electrical and/or voltage of the building facility's electricity consumption; and
one or more electricity storage stations for storing electrical energy regenerated in one of the building facilities.

10. The interactive system of claim 9, further comprising
one or more photovoltaic solar electricity generation units, comprising: one or more building windows and building glass wall coated with transparent photovoltaic material and electrically connected to the electricity storage station;
a ventilation system comprising one or more ventilation ports located above at least one of the building lift shafts,
wherein at least one of the ventilation ports is installed with one or more of the coated building windows which are caused to open for heat dissipation;
excess electricity generated by the one or more photovoltaic solar electricity generation units is redistributed into an electricity distribution network; and
the excess electricity and the present carbon dioxide emission are used in carbon trading computation.

11. The interactive system of claim 9, further comprising
one or more solar thermal-energy exchange units comprising one or more building windows coated with transparent thermal absorbing material and connected to a thermal-electricity conversion layer which is a piezoelectric coating on the coated building window electrically connected to the electricity storage station;
a ventilation system comprising one or more ventilation ports located above at least one of the building lift shafts;
wherein at least one of the ventilation ports is installed with one or more of the coated building windows which are closed for energy generation from the lift shafts heat under normal condition and are caused to open for heat dissipation;
excess electricity generated by the one or more solar thermal-energy exchange units is redistributed into an electricity distribution network; and
the excess electricity and the present carbon dioxide emission are used in carbon trading computation.

12. The interactive system of claim 1, wherein the sensing modules further comprise:
one or more garbage and kitchen energy storage conversion sensors for collecting and monitoring waste and kitchen energy storage data of the building and transmitting the data to the control center for integrating a garbage and kitchen waste energy storage tracking and data system;
one or more regenerative energy sensors for collecting and monitoring regenerative energy data of the building, and transmitting the data to the control center for integrating a regenerative energy storage tracking and data system;
one or more endothermic pressure layer conversion sensors for collecting and monitoring the endothermic pressure layer energy storage data of the building, and transmitting the data to the control center for integrating an endothermic pressure layer energy storage tracking and data system;
one or more solar thermal absorption coating conversion sensors for collecting and monitoring the solar thermal absorption coating energy storage data of the building and transmitting the data to the control center for integrating a solar thermal absorption coating energy storage tracking and data system;
one or more electroplating film thermal energy absorption coating conversion sensors for collecting and monitoring electroplating film thermal energy absorption coating energy storage data of the building and transmitting the data to the control center for integrating a electroplating film thermal energy coating energy storage tracking and data system;
one or more anodized film thermal energy absorption coating conversion sensor for collecting and monitoring anodized film thermal energy absorption coating energy storage data of the building and transmitting the data to the control center for integrating a anodized film energy storage tracking and data system;
one or more vacuum deposition thermal energy absorption coating conversion sensors for collecting and monitoring vacuum deposition thermal energy absorption coating energy storage data of the building and transmitting the data to the control center for integrating a vacuum deposition energy storage tracking and data system; and
one or more solar selective absorption coating sensor for collecting and monitoring solar energy selective absorption coating energy storage data of the building and transmitting data to the control center for integrating a solar selective absorption coating energy storage tracking and data system.

13. The interactive system of claim 1, further comprising
one or more cameras, installed in a lift shaft or a lift car in the lift shaft of the elevator, for capturing videos or images of the lift car or lift shaft; and
an elevator controller for controlling the lift car; and
an unintended car movement protection (UCMP) unit comprising a mechanical rope gripper;
wherein the one or more processors are further configured to
receive the captured videos or images of the lift car or lift shaft from the camera;
process the received videos or images and detect, using artificial intelligence, abnormal incidents happening inside the lift car or lift shaft; and
transmit an emergency call to the control center and an emergency instruction signal to the elevator controller or the UCMP unit when one or more abnormal incident is detected.

14. The interactive system of claim 13, wherein
the abnormal incidents include: abnormal human body movements or gestures which are suspected to be caused by criminal actions or fatal accidents; unintended opening or close of lift door; unintended movement of the lift car; over-speeding of the movement of the lift car; breaking of cables in suspension means connected to the lift car; damaging of a main drive brake or existence of one or more obstacles in movement path of the lift car; and
the emergency instruction signal sent to the elevator controller includes any one or a combination of: stopping the lift car immediately with the UCMP unit; moving the lift car to a safety floor; or activating an alarm in the lift car.

15. The interactive system of claim 1, further comprising a central device for accessing a cloud server by means of SSL, or HTML convergence, a centralized access platform (Masslink), and a connected network user interface to form an intelligent system.

16. A method for monitoring and reporting one or more building facilities' life cycle, maintenance, and metrics audit, comprising:
collecting, with one or more sensing modules, operation data of the one or more building facilities;
receiving and storing, with one or more processors, the collected operation data;
simulating, with the processers, a building information model (BIM) of the building and construct a three-dimensional model of the building using the collected operation data;
generating, with the processers, the one or more building facilities' life cycle, maintenance, and metrics audit reports using the collected operation data;
computing, with the processors, a present carbon dioxide emission of the building;
predicting, with the processors, a future carbon dioxide emission of the building;
communicating, with one or more communication modules respectively connected to one of the processors, for communicating with the processors and a control center;
estimating the heat transfer between the building and external environments by calculating the overall thermal transfer value (OTTV) of surfaces of one or more exterior building walls and roofs including glass lift shafts;
measuring, with one or more electrical transformers, electrical and/or voltage of the building facility's electricity consumption;
storing, with one or more electricity storage stations, electrical energy regenerated in one of the building facilities;
redistributing the regenereated electrical energy into an electricity distribution network;
collecting lift operation data comprising cable tension profile and loading of at least one of the buildings' lifts with one or more load sensors; wherein each of the load sensors is installed on a suspension means in one of the buildings' lifts; and
collecting noise data for determination of the load distribution evenness of the cables of at least one of the buildings' lifts with one or more noise sensors; wherein each of the noise sensors is installed on a suspension means in one of the buildings' lifts.

17. The method of claim 16, further comprising
converting, with one or more photovoltaic solar electricity generation units, solar energy into electrical energy, or one or more solar thermal-energy exchange units, solar energy into electrical energy;
wherein the photovoltaic solar electricity generation units comprise one or more building windows and building glass wall coated with transparent photovoltaic material and electrically connected to the electricity storage station; and wherein solar thermal-energy exchange units comprise one or more building windows coated with transparent thermal absorbing material and connected to a thermal-electricity conversion layer; wherein the thermal-electricity conversion layer is a piezoelectric coating on the coated building window electrically connected to the electricity storage station.

18. The method of claim 16, further comprising:
capturing, with one or more cameras installed in a lift shaft or a lift car in the lift shaft of the elevator, videos or images of the lift car or lift shaft;
measuring, with a processor, the lift movement speeds of the lift cars;
predicting, with the processor, passenger flow; and;
receiving, with the processor, the captured videos or images of the lift car or lift shaft from the camera;
processing, with the processor, the received videos or images and detecting, using artificial intelligence, abnormal incidents happening inside the lift car or lift shaft; and
transmitting an emergency call to a control center and an emergency instruction signal to a controller or an unintended car movement protection (UCMP) unit when one or more abnormal incident is detected; wherein the abnormal incidents include: abnormal human body movements or gestures which are suspected to be caused by criminal actions or fatal accidents; unintended opening or close of lift door; over-speeding of the movement of the lift car; unintended movement of the lift car; breaking of cables in suspension means connected to the lift car; or existence of one or more obstacles in movement path of the lift car; and
the emergency instruction signal sent to the elevator controller includes any one or a combination of: stopping the lift car immediately with the UCMP unit; moving the lift car to a safety floor; and activating an alarm in the lift car.

19. An intelligent system for monitoring and controlling an elevator, comprises:
one or more cameras, installed in a lift shaft or a lift car in the lift shaft of the elevator, for capturing videos or images of the lift car or lift shaft;
a processor configured to
receive the captured videos or images of the lift car or lift shaft from the camera;
process the received videos or images;
measure the lift movement speeds of the lift cars;
predict passenger flow; and
detect, using artificial intelligence, abnormal incidents happening inside the lift car or lift shaft;
an elevator controller for controlling the lift car; and
an unintended car movement protection (UCMP) unit comprising a mechanical rope gripper;
wherein the processor is configured to transmit an emergency call to a control center and an emergency instruction signal to the controller or the UCMP unit when one or more abnormal incident is detected.

20. The intelligent system of claim 19, wherein
the abnormal incidents include any one of: abnormal human body movements or gestures which are suspected to be caused by criminal actions or fatal accidents; unintended opening or close of lift door; over-speeding of the movement of the lift car; unintended movement of the lift car; breaking of cables in suspension means connected to the lift car; or existence of one or more obstacles in movement path of the lift car; and
the emergency instruction signal sent to the elevator controller includes any one or a combination of: stopping the lift car immediately with the UCMP unit; moving the lift car to a safety floor; and activating an alarm in the lift car.
